(19) United States
(12) Patent Application Publication
(10) Pub. No.: US 2017/0084871 A1
(43) Pub. Date: Mar. 23, 2017

(54) TOUCH CONTROL ORGANIC LIGHT-EMITTING DISPLAY PANEL

(71) Applicant: EVERDISPLAY OPTRONICS (SHANGHAI) LIMITED, SHANGHAI CITY (CN)

(72) Inventors: Mingyue ZHANG, SHANGHAI CITY (CN); Zhengjie YANG, SHANGHAI CITY (CN); Chungche TSOU, SHANGHAI CITY (CN); PingI SHIH, SHANGHAI CITY (CN)

(73) Assignee: EVERDISPLAY OPTRONICS (SHANGHAI) LIMITED, SHANGHAI CITY (CN)

(21) Appl. No.: 15/177,850

(22) Filed: Jun. 9, 2016

(30) Foreign Application Priority Data
Sep. 22, 2015 (CN) 201510607184.2

(51) Int. Cl. H01L 51/52; H01L 27/32

(52) U.S. Cl. CPC H01L 51/5271; H01L 27/323; H01L 51/5293; H01L 51/5253; H01L 27/3244; H01L 2251/5338; H01L 2251/5315

(57) ABSTRACT

The present disclosure relates to an organic light-emitting display panel. A dielectric layer having a specific Bragg reflector layer structure is disposed between a polarizer and an organic light-emitting diode device or between a polarizer and a touch control panel. In the first aspect, blue light below 438 nm harmful to human eyes may be greatly reduced. The Bragg reflector layer structure may not only play a role of micro-cavity control, but also form a resonant cavity effect corresponding to organic optical micro-cavities in the device, which achieves effect of controlling spectrum and improving color purity, of the control panel. Different Bragg reflector layer structures may be designed according to different devices and different requirements, to achieve a better effect of protecting human eyes. Besides, the Bragg reflector layer of the dielectric layer may further enhance performance of preventing water and oxygen and improve encapsulation effect.

### CROSS-REFERENCE TO RELATED APPLICATIONS

The present application is based upon and claims priority to Chinese Patent Application No. 201510607184.2, filed Sep. 22, 2015, the entire contents of which are incorporated herein by reference.

### TECHNICAL FIELD

The present disclosure generally relates to an organic light-emitting display panel, and more particularly, to a touch control organic light-emitting display panel.

### BACKGROUND

OLED (organic light-emitting diode) display technology has self-luminous characteristic. Using very thin organic material coating and glass substrate, the organic material may emit light when current passes. Besides, OLED display screens have large viewing angles, and may save electric energy significantly. Because the OLED display technology has incomparable advantage over many LED (light-emitting diode) display technology, it has been widely applied in the display field.

For example, the organic light-emitting diode display panels may combine with touch control panels to form touch control display panels. However, when present touch control organic light-emitting display panels emit visible light, they also emit blue light harmful to human eyes (below 438 nm), and the harmful blue light is pretty strong. Besides, because OLED devices are very sensitive to water vapor and oxygen, organic functional layers and material of electrodes may be corroded once water vapor and oxygen permeate in, which seriously influences the life of the devices.

### SUMMARY

With respect to above problems and/or other problems in the related art, the present disclosure provides a touch control organic light-emitting display panel, including: an organic light-emitting diode device; a polarizer, laminated above a light-exiting surface of the organic light-emitting diode device; a touch control panel, disposed above the polarizer; and a dielectric layer, disposed between the polarizer and the organic light-emitting diode device, or between the polarizer and the touch control panel, wherein the dielectric layer includes: a thin film substrate, and a Bragg reflector layer, formed above the thin film substrate, wherein the Bragg reflector layer includes a first layer and a second layer alternatively laminated along a thickness direction, the second layer has a refractive index higher than that of the first layer by at least 0.5, and the first layer is the closest to the thin film substrate, the Bragg reflector layer has n layers of the first layer and n layers of the second layer, and n is a positive integer greater than or equal to 1 and less than or equal to 5, and the Bragg reflector layer has a reflectivity of 95%-100% to blue light below 438 nm.

According to another aspect of the present disclosure, there is provided an electronic device, having the above touch control organic light-emitting display panel.

Through a lot of research, the inventor of the present disclosure found that, by disposing the dielectric layer having the specific Bragg reflector layer structure between the polarizer and the organic light-emitting diode device or between the polarizer and the touch control panel, the touch control organic light-emitting display panel of the present disclosure may produce the following beneficial effect. In the first aspect, blue light below 438 nm harmful to human eyes may be greatly reduced, such that an aim of protecting human eyes may be achieved. In the second aspect, the inventor of the present disclosure further found that, the structure of the Bragg reflector layer in the dielectric layer may not only play a role of micro-cavity control, but also form a resonant cavity effect corresponding to organic optical micro-cavities in the oganic light emitting diode device, such that it may achieve effect of controlling spectrum and improving color purity, of the control panel. In the third aspect, the dielectric layer is not disposed in the internal area of the oganic light emitting diode device, but is of an outer adhering type, and adheres to the outside the device, thus different structures of the Bragg reflector layer may be designed according to different devices and different requirements, such that it may achieve a better effect of protecting human eyes. At last, the dielectric layer, especially the Bragg reflector layer of the dielectric layer may further enhance performance of preventing water and oxygen and improve encapsulation effect of the organic light-emitting diode device.

### BRIEF DESCRIPTION OF THE DRAWINGS

FIG. 1 is a schematic diagram of a touch control organic light-emitting display panel according to Embodiment 1 of the present disclosure;

FIG. 2 is a structural schematic diagram of a dielectric layer of the touch control organic light-emitting display panel as shown in FIG. 1;

FIG. 3 is a schematic diagram of a touch control organic light-emitting display panel according to Embodiment 2 of the present disclosure; and

FIG. 4 is a comparison diagram of spectra of the touch control organic light-emitting display panel according to the Embodiment 1 of the present disclosure and an existing product, wherein R represents red light, G represents green light, B represents blue light, a dashed line represents a product according to Embodiment 1, and a solid line represents the existing product.

### DESCRIPTION OF THE EMBODIMENTS

The exemplary implementations of the present disclosure will now be described more fully with reference to the accompanying drawings. However, the exemplary implementations can be implemented in various forms and should not be understood as being limited to the implementations set forth herein; instead, these implementations are provided so that this disclosure will be thorough and complete, and the conception of exemplary implementations will be fully conveyed to those skilled in the art. In the drawings, the same reference numerals denote the same or similar structures, thus their detailed description will be omitted.

The described features, structures, or characteristics may be combined in one or more embodiments in any suitable manner. In the following description, numerous specific details are provided so as to allow a full understanding of the embodiments of the present disclosure. However, those skilled in the art will recognize that the technical solutions of the present disclosure may be practiced without one or more of the specific details, or other methods, components, materials and so on may be used. In other cases, well-known structures, materials or operations are not shown or described in detail to avoid obscuring various aspects of the present disclosure.

“Formed/located/laminated above” described in the present disclosure should be understood as including “Formed/located/laminated on” with direct contact and “Formed/located/laminated over” with indirect contact.

Drawings of the present disclosure are provided for illustrating relative position relations only, thicknesses of some portions are exaggerated for the convenience of understanding, and thicknesses in the drawings does not represent actual scale of the thicknesses of layers.

### Embodiment 1

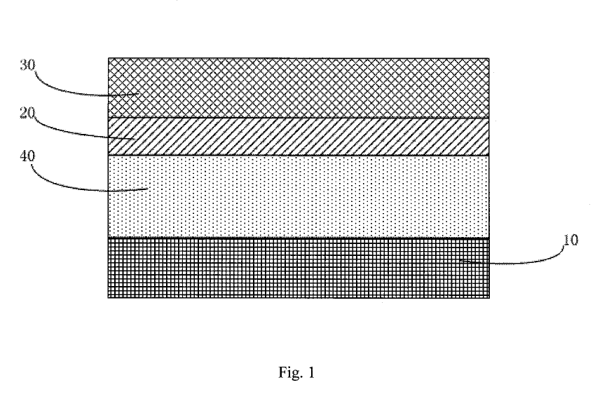

FIG. 1 is a schematic diagram of a touch control organic light-emitting display panel according to Embodiment 1 of the present disclosure, which includes: an organic light-emitting diode device 10; a polarizer 20 laminated above a light-exiting surface of the organic light-emitting diode device 10; a touch control panel 30 disposed above the polarizer 20, and a dielectric layer 40 disposed between the polarizer 20 and the organic light-emitting diode device 10.

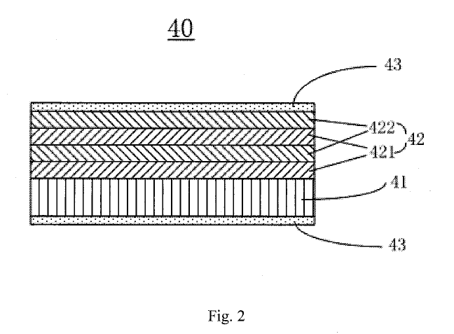

Referring to FIG. 2, the dielectric layer 40 includes a thin film substrate 41 and a Bragg reflector layer 42 formed above the thin film substrate.

The Bragg reflector layer 42 includes a first layer 421 and a second layer 422 alternatively laminated along a thickness direction, the second layer 422 has a refractive index higher than that of the first layer 421 by at least 0.5, and the first layer 421 is the closest to the thin film substrate 41. The Bragg reflector layer 42 has n layers of the first layer 421 and n layers of the second layer 422, wherein n is a positive integer greater than or equal to 1 and less than or equal to 5. The Bragg reflector layer 42 has a reflectivity of 95%˜100% to blue light below 438 nm.

According to the present embodiment, an upper surface and a lower surface of the dielectric layer 40 are respectively coated with OCA (optically clear adhesive) layers 43, thus, the upper surface and the lower surface respectively adhere to the polarizer 20 and the light-exiting surface of the organic light-emitting diode 10 by pasting the OCA layers 43.

According to another alternative embodiment, after the upper surface and the lower surface of the dielectric layer 40 respectively adhere to the polarizer 20 and the light-exiting surface of the organic light-emitting diode 10, an end face seal process is conducted, thus, the dielectric layer 40 is tightly combined with the polarizer 20 and the light-exiting surface of the organic light-emitting diode 10.

For example, a total thickness of the Bragg reflector layer is 200 nm˜1000 nm.

For example, the above first layer 421 and second layer 422 may include material selected from a group consisting of SiO₂, Si, SiC, Si₃N₄, TiO₂, Al₂O₃, MgO, BeO, CaF₂, ZnSe and MgF₂, as long as the refractive index of the second layer 422 is higher than that of the first layer 421 by at least 0.5.

According to the present embodiment, the first layer 421 is SiO₂, whose refractive index is 1.55, and the second layer 422 is SiC, whose refractive index is 2.65. For example, n equals 2, thicknesses of the first layer 421 and second layer 422 are both 100 nm That is, the total thickness of the Bragg reflector layer 42 is 400 nm The reflectivity of the Bragg reflector layer 42 is 96% to blue light below 438 nm.

According to the present embodiment, material of the thin film substrate 41 may be optical material COP (cyclo-olefin polymer), with a thickness of 50 um. The thin film substrate 41 may be of PET (polyethylene terephthalate) or other material, for example, material suitable for serving as the Bragg reflector layer 42, which has little influence on optical performance of the entire display panel, and may endure high temperature above 160° C. The thickness of the thin film substrate 41 had better not influence the optical performance, and the thinner the thickness of the thin film substrate 41 is, the better the optical performance is.

According to the present embodiment, the respective layers of the Bragg reflector layer 42 are formed in sequence by depositing above the thin film substrate 41 through a low-temperature chemical vapor deposition method or a wet process coating method.

According to the present embodiment, the organic light-emitting diode device 10 is a flexible AMOLED device.

According to the present embodiment, the organic light-emitting diode device 10 is a top-emitting type device.

### Embodiment 2

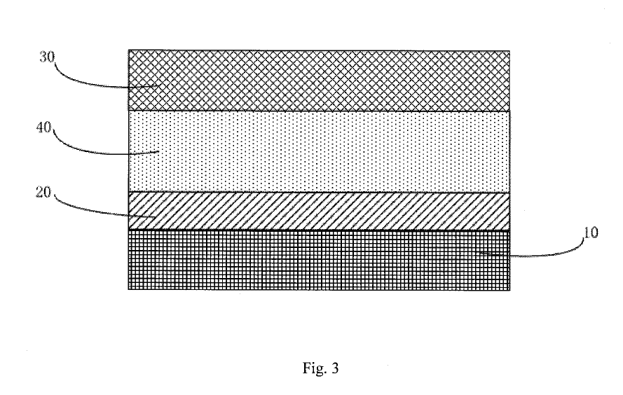

FIG. 3 is a schematic diagram of a touch control organic light-emitting display panel according to Embodiment 2 of the present disclosure.

It mainly differs from Embodiment 1 in that: the dielectric layer 40 is disposed between the polarizer 20 and the touch control panel 30.

Other layers are the same as that of Embodiment 1, which will be not repeatedly illustrated herein.

Through a lot of research, the inventor of the present disclosure found that, by disposing the dielectric layer 40 having the specific Bragg reflector layer structure between the polarizer 20 and the organic light-emitting diode device 10 or between the polarizer 20 and the touch control panel 30, the touch control organic light-emitting display panel of the present disclosure may produce the following beneficial effect. In the first aspect, blue light below 438 nm harmful to human eyes may be greatly reduced, such that an aim of protecting human eyes may be achieved. In the second aspect, the inventor of the present disclosure further found that, the structure of the Bragg reflector layer 42 in the dielectric layer 40 may not only play a role of micro-cavity control, but also form a resonant cavity effect corresponding to organic optical micro-cavities in the oganic light emitting diode device, such that it may achieve effect of controlling spectrum and improving color purity, of the control panel. In the third aspect, the dielectric layer 40 is not disposed in the internal area of the oganic light emitting diode device, but is of an outer adhering type, and adheres to the outside the device, thus different structures of the Bragg reflector layer 42 may be designed according to different devices and different requirements, such that it may achieve a better effect of protecting human eyes. At last, the dielectric layer 40, especially the Bragg reflector layer 42 of the dielectric layer 40 may further enhance performance of preventing water and oxygen and improve encapsulation effect of the organic light-emitting diode device 10.

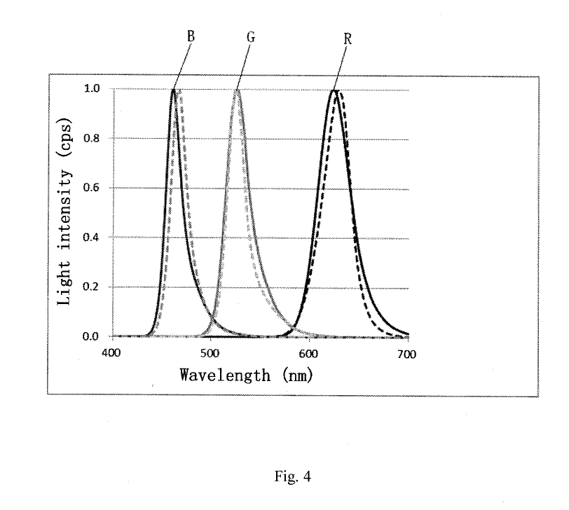

FIG. 4 is a comparison diagram of spectrum of a touch control organic light-emitting display panel according to Embodiment 1 of the present disclosure and an existing product. The difference between the existing product and the display panel according to Embodiment 1 is in that the existing product is not provided with the dielectric layer 40.

It can be seen from FIG. 4 that, after the dielectric layer 40 having the structure of the Bragg reflector layer 42 is added, the spectrum of blue light right shifts. After calculation, blue light below 438 nm reduces by 33%. That is, blue light below 438 nm harmful to human eyes is greatly reduced, such that a good eyes protecting effect is obtained.

It should be noted that the present specification is described according to implementations, however, each implementation may involve different technical solutions. The descriptions in the present specification are provided for clarity. Those skilled in the art should regard the specification as a whole, and technical solutions in each implementation may also be combined appropriately to form other implementations that are available to those skilled in the art.

Detailed descriptions hereinabove are provided only for describing possible implementations of the present disclosure in detail. They are not provided for limiting the protection scope of the present disclosure, and all the equivalent implementations and alternatives without going beyond the technical spirit of the present disclosure are involved in the protection scope of the present disclosure.

What is claimed is:

1. An organic light-emitting display panel, comprising:
an organic light-emitting diode device, comprising a light-exiting surface;
a polarizer, laminated above the light-exiting surface of the organic light-emitting diode device;
a touch control panel, disposed above the polarizer; and
a dielectric layer, disposed between the polarizer and the organic light-emitting diode device, or between the polarizer and the touch control panel,
wherein the dielectric layer comprises a Bragg reflector layer, the Bragg reflector layer at least comprises a first layer and a second layer alternatively laminated along a thickness direction, the second layer has a refractive index higher than that of the first layer by at least 0.5, and the Bragg reflector layer has a reflectivity of 95%˜100% to light wave length below 438 nm of blue light.

2. The organic light-emitting display panel according to claim 1, wherein the Bragg reflector layer has n layers of the first layer and n layers of the second layer, and n is a positive integer greater than or equal to 1 and less than or equal to 5.

3. The organic light-emitting display panel according to claim 1, wherein the Bragg reflector layer further comprises a thin film substrate, and distance between the first layer and the thin film substrate is smaller than that between the second layer and thin film substrate.

4. The organic light-emitting display panel according to claim 1, wherein an upper surface and a lower surface of the dielectric layer are coated with an optically clear adhesive layer.

5. The organic light-emitting display panel according to claim 1, wherein a total thickness of the Bragg reflector layer is 200 nm˜1000 nm.

6. The organic light-emitting display panel according to claim 1, wherein material of the thin film substrate is optical material COP or PET.

7. The organic light-emitting display panel according to claim 1, wherein the first layer and the second layer comprise material selected from a group consisting of SiO₂, Si, SiC, Si₃N₄, TiO₂, Al₂O₃, MgO, BeO, CaF₂, ZnSe and MgF₂.

8. The organic light-emitting display panel according to claim 2, wherein the first layer and the second layer comprise material selected from a group consisting of SiO₂, Si, SiC, Si₃N₄, TiO₂, Al₂O₃, MgO, BeO, CaF₂, ZnSe and MgF₂.

9. The organic light-emitting display panel according to claim 3, wherein the first layer and the second layer comprise material selected from a group consisting of SiO₂, Si, SiC, Si₃N₄, TiO₂, Al₂O₃, MgO, BeO, CaF₂, ZnSe and MgF₂.

10. The organic light-emitting display panel according to claim 4, wherein the first layer and the second layer comprise material selected from a group consisting of SiO₂, Si, SiC, Si₃N₄, TiO₂, Al₂O₃, MgO, BeO, CaF₂, ZnSe and MgF₂.

11. The organic light-emitting display panel according to claim 7, wherein the material of the first layer is SiO₂ and the material of the second layer is SiC.

12. The organic light-emitting display panel according to claim 8, wherein the material of the first layer is SiO₂ and the material of the second layer is SiC.

13. The organic light-emitting display panel according to claim 9, wherein the material of the first layer is SiO₂ and the material of the second layer is SiC.

14. The organic light-emitting display panel according to claim 10, wherein the material of the first layer is SiO₂ and the material of the second layer is SiC.

15. The organic light-emitting display panel according to claim 1, wherein the organic light-emitting diode device is a flexible OLED device or a flexible AMOLED device.

16. The organic light-emitting display panel according to claim 2, wherein the organic light-emitting diode device is a flexible OLED device or a flexible AMOLED device.

17. The organic light-emitting display panel according to claim 3, wherein the organic light-emitting diode device is a flexible OLED device or a flexible AMOLED device.

18. The organic light-emitting display panel according to claim 4, wherein the organic light-emitting diode device is a flexible OLED device or a flexible AMOLED device.

19. The organic light-emitting display panel according to claim 1, wherein the organic light-emitting diode device is a top-emitting type device.

20. The organic light-emitting display panel according to claim 2, wherein the organic light-emitting diode device is a top-emitting type device.

21. The organic light-emitting display panel according to claim 3, wherein the organic light-emitting diode device is a top-emitting type device.

22. The organic light-emitting display panel according to claim 4, wherein the organic light-emitting diode device is a top-emitting type device.

23. An electronic device, having the organic light-emitting display panel according to claim 1.
